(19) United States
(12) Patent Application Publication
(10) Pub. No.: US 2005/0011767 A1
(43) Pub. Date: Jan. 20, 2005

(54) Manufacturing method for a magnetic recording medium stamp and manufacturing apparatus for a magnetic recording medium stamp

(75) Inventors: Katsuyuki Nakada, Tokyo (JP); Mitsuru Takai, Tokyo (JP); Kazuhiro Hattori, Tokyo (JP)

Correspondence Address: GREENBLUM & BERNSTEIN, P.L.C., 1950 ROLAND CLARKE PLACE, RESTON, VA, 20191, US

(73) Assignee: TDK Corporation, Tokyo (JP)

(21) Appl. No.: 10/890,986

(22) Filed: Jul. 15, 2004

(30) Foreign Application Priority Data
Jul. 17, 2003 (JP) 2003-198201

(51) Int. Cl. C23C 16/00

(52) U.S. Cl. 205/122; 427/248.1; 427/299

(57) ABSTRACT

A manufacturing method for a magnetic recording medium stamp manufactures a magnetic recording medium stamp for manufacturing a discrete track-type magnetic recording medium. The manufacturing method includes a step of forming a convex/concave pattern in a resin layer formed on a support substrate, a step of forming a conductive film so as to cover the convex/concave pattern and then forming a metal film on the conductive film by carrying out a plating process, and a step of separating a multilayer structure composed of the conductive film and the metal film from the support substrate.

### BACKGROUND OF THE INVENTION

1. Field of the Invention

The present invention relates to a manufacturing method for a magnetic recording medium stamp that manufactures a magnetic recording medium stamp used for manufacturing a discrete track-type magnetic recording medium and a manufacturing apparatus for a magnetic recording medium stamp.

2. Description of the Related Art

As one example of a manufacturing method for a stamp used for manufacturing an information recording medium such as a magnetic recording medium, Japanese Laid-Open Patent Publication No. H05-205321 discloses a manufacturing method for a stamp composed of a conductive film and an electroformed film. In this manufacturing method, first a photoresist coated on a quartz glass plate is irradiated with laser light and then developed to form a fine pattern on the quartz glass plate. Next, the quartz glass plate is etched with the fine pattern being used as a mask, so that concave parts are formed in the quartz glass plate, thereby forming a master matrix. After this, the conductive film is formed by sputtering on the surface of the master matrix, and the electroformed film is formed by carrying out an electroforming process using the conductive film. After this, the multilayer structure composed of the conductive film and the electroformed film are separated from a master matrix to complete the stamp.

However, by investigating the conventional manufacturing method for a stamp, the present inventors discovered the following problem. That is, according to the conventional manufacturing method, the stamp is manufactured by forming the conductive film and the electroformed film on a master matrix formed by etching a quartz glass plate with a fine pattern as a mask. On the other hand, when manufacturing discrete track-type magnetic recording media (hereinafter also referred to as “discrete track media”) that have been subject to attention as next-generation magnetic recording media, to raise the density with which data is recorded, it is necessary to reduce the track pitch of the data recording tracks by a certain extent. Accordingly, it is necessary to make the groove parts (non-magnetic parts for reducing the magnetic effects on adjacent data recording tracks during the recording or reproduction of data) formed in the magnetic material layer quite narrow.

In this case, as shown in FIG. 11, when the groove parts are formed by etching a metal mask layer and a magnetic material layer using a mask M formed using a resist, for example, as shown by the broken line in FIG. 11, the etched width tends to become narrower as the distance from the mask M increases (moving downwards in FIG. 11). For this reason, when the width W2 of the convex parts in the mask M is too wide and the formation pitch of the data recording tracks is not changed, it may be difficult to form the groove parts with a depth that reaches the substrate. Additionally, when the height H2 of the mask M is too low, the mask M will disappear in a short time during etching, so that it will be difficult to carry out etching for a sufficient time for forming the groove parts in the magnetic material layer. This means that to form the groove parts in the magnetic material layer by etching, it is necessary to form the convex parts in the mask M with a high aspect ratio (height H2/width W2). Accordingly, when the mask M is formed by an imprinting method, it is necessary to use a stamp (a magnetic recording medium stamp) with a convex/concave pattern including concave parts with a sufficiently high aspect ratio (depth of the concave parts/width of the concave parts).

On the other hand, when a stamp that has a convex/concave pattern with concave parts of a high aspect ratio is manufactured according to a conventional manufacturing method, it is necessary to increase the aspect ratio of the convex parts formed in the quartz glass plate. Accordingly, it becomes necessary to sufficiently raise the aspect ratio of convex parts (parts that cover the quartz glass plate) in the fine pattern (a mask made of a photoresist) used to form the concave parts in the quartz glass plate by etching. However, when a fine pattern including convex parts with a high aspect ratio is formed by exposing and developing a photoresist, there are cases where the pattern (the convex parts) collapses, such as when a photoresist for which exposure is complete is soaked in developer liquid or when a fine pattern for which developing is complete is soaked in a rinsing solution. Such collapsing of the pattern occurs more prevalently as the aspect ratio of the convex parts of the fine pattern becomes large (collapsing becomes more likely), so that with the conventional manufacturing method, there is the problem that it is difficult to manufacture a stamp having concave parts with a high aspect ratio.

### SUMMARY OF THE INVENTION

The present invention was conceived in order to solve the problem described above and it is a principal object of the present invention to provide a manufacturing method for a magnetic recording medium stamp that can easily manufacture a magnetic recording medium stamp having concave parts with a high aspect ratio and a manufacturing apparatus for a magnetic recording medium stamp.

To achieve the stated object, a manufacturing method for a magnetic recording medium stamp according to the present invention manufactures a magnetic recording medium stamp for manufacturing a discrete track-type magnetic recording medium, the method including: a step of forming a convex/concave pattern in a resin layer formed on a support substrate; a step of forming a conductive film so as to cover the convex/concave pattern and then forming a metal film on the conductive film by carrying out a plating process; and a step of separating a multilayer structure composed of the conductive film and the metal film from the support substrate. It should be noted that a “discrete track-type magnetic recording medium” for the present invention is not only a magnetic recording medium having a data recording region in which adjacent data recording tracks (magnetic material parts) are magnetically isolated from each other by a plurality of grooves formed in concentric circles or grooves formed in spirals, and also includes a so-called “patterned medium” where the data recording region is partitioned into a mesh or dots (each data recording track is magnetically isolated into a plurality of parts in the length direction) and the formed data recording parts (magnetic material parts) are isolated in the form of islands.

A manufacturing apparatus for a magnetic recording medium stamp according to the present invention manufactures a magnetic recording medium stamp for manufacturing a discrete track-type magnetic recording medium, the manufacturing apparatus including: a resin layer forming device that forms a resin layer on a support substrate; a convex/concave pattern forming device that forms a convex/concave pattern in the resin layer; a conductive film forming device that forms a conductive film so as to cover the convex/concave pattern; and a metal film forming device that forms a metal film on the conductive film by carrying out a plating process.

With the manufacturing method for a magnetic recording medium stamp and the manufacturing apparatus for a magnetic recording medium stamp according to the present invention, a magnetic recording medium stamp is manufactured by forming a conductive film so as to cover a convex/concave pattern formed in a resin layer on a support substrate and then forming a metal film by carrying out a plating process, so that it is possible to easily manufacture a magnetic recording medium stamp having concave parts with a high aspect ratio without making such a large increase in the aspect ratio of the convex parts in the resist pattern for forming the magnetic recording medium stamp.

With the above manufacturing method, it is preferable that out of convex parts of the convex/concave pattern, convex parts for forming concave parts in parts of the stamp that correspond to a data recording region of a magnetic recording medium are formed with an aspect ratio (given as the height of the convex parts/the width of the convex parts) of 1 or above. Here, it is more preferable to form the convex parts so that the aspect ratio is in a range of 1 to 3, inclusive. It should be noted that the “data recording region of the magnetic recording medium” for the present invention is a region in which data can be magnetically written. Accordingly, a region in which a servo pattern for tracking purposes (a servo recording region) and a standby region for a magnetic head are not included in the “data recording region” for the present invention. With this preferred aspect, it is possible to reliably manufacture a magnetic recording medium stamp that can manufacture a magnetic recording medium on which data can be recorded with a sufficiently high density.

With the above manufacturing method, it is also preferable to form the convex/concave pattern by irradiating an exposure beam to a resist layer as the resin layer to form a latent image and then developing the resist layer. Also, with the above manufacturing apparatus, the convex/concave pattern forming device should preferably include an exposing device that irradiates an exposure beam to a resist layer as the resin layer to form a latent image and a developing device that forms a convex/concave pattern by developing the resist layer in which the latent image has been formed. According to this preferred aspect, it is possible to easily form the convex/concave pattern for manufacturing the magnetic recording medium stamp without using any special equipment.

In addition, with the above manufacturing method, it is preferable to form the convex/concave pattern by an imprinting method. Also, in the above manufacturing apparatus, the convex/concave pattern forming device should preferably include an imprinting device that forms the convex/concave pattern by carrying out an imprinting method. According to this preferred aspect, since it is possible to form the convex/concave pattern without soaking in developer liquid or rinsing liquid, it is possible to reliably avoid the collapsing of the convex parts, even in cases where convex parts with a high aspect ratio are formed. Accordingly, it is possible to manufacture a magnetic recording medium stamp having concave parts with a high aspect ratio even more reliably.

It should be noted that the disclosure of the present invention relates to a content of Japanese Patent Application 2003-198201 that was filed on 17 Jul. 2003 and the entire content of which is herein incorporated by reference.

### BRIEF DESCRIPTION OF THE DRAWINGS

These and other objects and features of the present invention will be explained in more detail below with reference to the attached drawings, wherein:

FIG. 1 is a cross-sectional view of a stamp manufactured according to the manufacturing method according to an embodiment of the present invention;

FIG. 2 is a block diagram showing the construction of a stamp manufacturing apparatus according to an embodiment of the present invention;

FIG. 3 is a cross-sectional view of a state where a resist layer has been formed on a substrate;

FIG. 4 is a cross-sectional view of a state where a latent image has been formed by irradiating an electron beam to the resist layer;

FIG. 5 is a cross-sectional view of a state where the developing of the resist layer (the formation of the resist pattern) has been completed;

FIG. 6 is a cross-sectional view of a state where a conductive film has been formed so as to cover the resist pattern;

FIG. 7 is a cross-sectional view useful in explaining shrinkage of the resist layer when the conductive film is formed;

FIG. 8 is a cross-sectional view of a state where a metal film has been formed on the conductive film;

FIG. 9 is a cross-sectional view of a state where a multilayer structure of the conductive film and the metal film (i.e., the stamp) has been separated;

FIG. 10 is a characteristics graph showing the relationship between the aspect ratio of convex parts in the resist pattern immediately after developing is completed and the aspect ratio of the concave parts of the stamp; and

FIG. 11 is a cross-sectional view useful in explaining a manufacturing method for a discrete track medium.

### DESCRIPTION OF THE PREFERRED EMBODIMENTS

Preferred embodiments of a magnetic recording medium stamp and a manufacturing apparatus for a magnetic recording medium stamp according to the present invention will now be described with reference to the attached drawings.

First, the construction of a magnetic recording medium stamp (hereinafter, the “stamp”) 1 according to an embodiment of the present invention and the construction of a stamp manufacturing apparatus 10 for manufacturing the stamp 1 will be described with reference to the drawings.

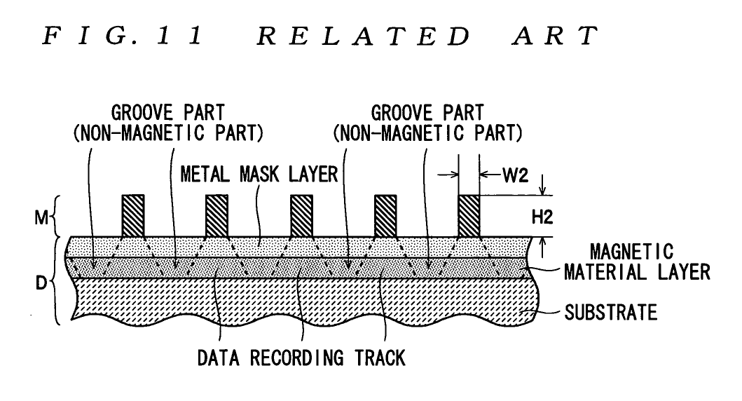

The stamp 1 shown in FIG. 1 is a stamp for forming a mask M by an imprinting method for forming (etching) groove parts in a magnetic material layer when manufacturing a discrete track medium D (see FIG. 11), and is composed of a conductive film 2 formed on a metal film 3. The conductive film 2 is formed by vapor-depositing a metal and has a thickness of around 30 nm. The metal film (electro nickel film) 3 is formed with a thickness of around 120 μm by carrying out an electroplating process (a deposition process) using the conductive film 2 as an electrode. As one example, the concave parts of the convex/concave pattern of the stamp 1 are formed with a depth (this is also the height of the convex parts and is hereinafter referred to as the “depth H2”) of around 130 nm and a width W2 of around 55 nm. By doing so, the aspect ratio (depth H2/width W2) of the concave parts is 2.36.

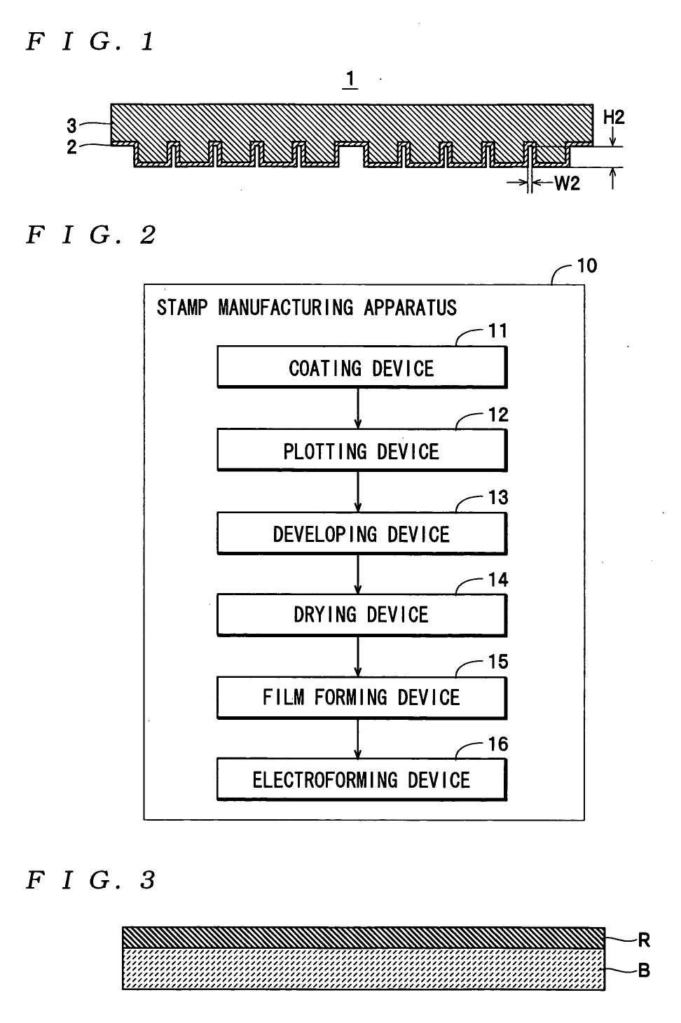

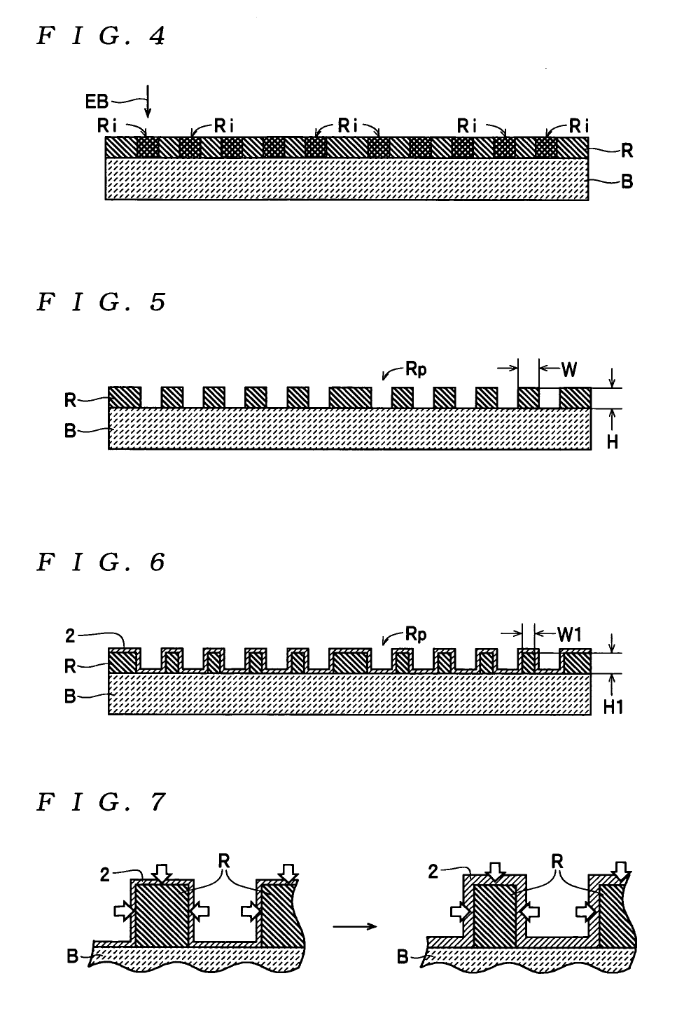

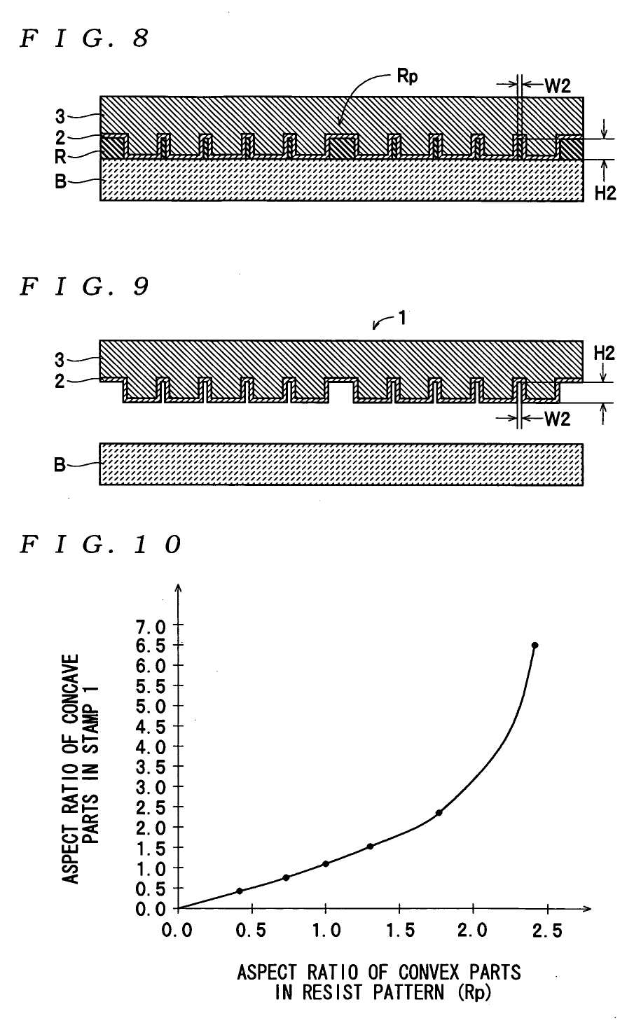

On the other hand, the stamp manufacturing apparatus 10 shown in FIG. 2 corresponds to a “manufacturing apparatus for a magnetic recording medium stamp” according to the present invention, is composed of a coating device 11, a plotting device 12, a developing device 13, a drying device 14, a film forming device 15, and an electroforming device 16, and is constructed so as to be capable of manufacturing the stamp 1. The coating device 11 corresponds to a “resin layer forming device” for the present invention, and, as shown in FIG. 3, forms a resist layer R (one example of a resin layer for the present invention) by coating a resist onto a substrate B by spin coating, for example. The plotting device 12 composes an “exposing device” for the present invention and together with the developing device 13 composes a “convex/concave pattern forming device” for the present invention. As shown in FIG. 4, the plotting device 12 forms a latent image Ri in the resist layer R by irradiating an electron beam EB (one example of an “exposure beam” for the present invention) onto the resist layer R on the substrate B. As shown in FIG. 5, the developing device 13 forms a resist pattern Rp (the “convex/concave pattern” for the present invention) on the substrate B by developing the resist layer R in which the formation of the latent image Ri has been completed. The drying device 14 dries the substrate B on which the formation of the resist pattern Rp has been completed. The film forming device 15 corresponds to a “conductive film forming device” for the present invention, and, as shown in FIG. 6, forms the conductive film 2 so as to cover the resist pattern Rp. The electroforming device 16 corresponds to a “metal film forming device” for the present invention, and, as shown in FIG. 8, forms the metal film 3 on the conductive film 2 by carrying out an electroplating process.

Next, a manufacturing method for the stamp 1 using the stamp manufacturing apparatus 10 will be described with reference to the drawings.

First, as shown in FIG. 3, the coating device 11 coats a resist (as one example, a positive-type electron beam resist) onto the substrate B using a spin coating method, thereby forming the resist layer R with a thickness of around 130 nm. In this case, the substrate B corresponds to a “support substrate” for the present invention, and as one example, a plate-like silicon substrate whose surface has been polished flat is used. Next, a baking process is carried out at 180° C. for around five minutes to harden the resist layer R, and the substrate B in this state is then set in the plotting device 12. Next, as shown in FIG. 4, the plotting device 12 irradiates the electron beam EB for patterning to positions where convex parts of the stamp 1 should be formed. By doing so, latent images Ri, Ri, . . . in the form of concentric circles with a formation pitch of around 150 nm and a width of around 76 nm are formed in the resist layer R. Next, by developing the resist layer R in this state, as shown in FIG. 5, the developing device 13 removes the latent image Ri parts to expose parts of the surface of the substrate B. Here, as one example, the product ZED-N50 (made by ZEON CORPORATION of Japan) is used as the developer liquid and the substrate B is soaked for three minutes with the developer liquid at 26° C. By doing so, the resist pattern Rp is formed on the substrate B. In this case, to stop the convex parts of the resist pattern Rp collapsing when the substrate B is soaked in the developer liquid and the rinsing liquid described later, it is preferable for the aspect ratio of the convex parts to be three or below. Next, after the substrate B in this state has been soaked in the rinsing liquid ZMD-D (made by ZEON CORPORATION of Japan) at a temperature of 23° C. (room temperature), the drying device 14 dries the resist pattern Rp (the resist layer R) by blowing nitrogen gas onto the substrate B. In this case, the resist pattern Rp that has been completely dried by the drying device 14 is formed so that the width W of the convex parts is around 74 nm and the height H is around 130 nm (resulting in an aspect ratio of around 1.76).

Next, as shown in FIG. 6, the film forming device 15 deposits nickel so as to cover the resist pattern Rp, thereby forming the conductive film 2 with a thickness of around 30 nm. At this time, a difference is produced between the membrane stress of the resist layer R in which the resist pattern Rp is formed and the membrane stress of the conductive film 2. Accordingly, as shown by the arrows in the left part of FIG. 7, forces act so as to cause the resist layer R (the convex parts of the resist pattern Rp) to shrink. As a result, at a point when the formation of the conductive film 2 is completed, as shown by the right part of FIG. 7 and FIG. 6, the width W1 of the convex parts of the resist pattern Rp is narrowed to around 67 nm, and the height H1 becomes slightly lower, so that the aspect ratio becomes 1.94. Next, as shown in FIG. 8, the electroforming device 16 carries out an electroplating process using the conductive film 2 as an electrode to form the metal film (an electro nickel film) 3 with a thickness of around 120 μm on the conductive film 2. At this time, a difference is produced between the membrane stress of the resist layer R in which the resist pattern Rp is formed and the membrane stress of the multilayer structure composed of the conductive film 2 and the metal film 3 (the multilayer structure that later forms the stamp 1). Accordingly, forces act so as to cause further shrinkage in the resist layer R (the convex parts of the resist pattern Rp). As a result, at a point when the formation of the metal film 3 is completed, the width W2 of the convex parts of the resist pattern Rp (in other words, the width W2 of the parts that will become the concave parts of the stamp 1) is narrowed to around 55 nm and the height H2 will become slightly lower, so that the aspect ratio becomes approximately 2.36. After this, the multilayer structure composed of the substrate B, the resist layer R, the conductive film 2, and the metal film 3 is soaked in resist removing liquid to dissolve the resist layer R so that as shown in FIG. 9, the multilayer structure of the conductive film 2 and the metal film 3 is separated from the substrate B. When carrying out this process, it is also possible to use a dedicated separating device (not shown). By doing so, as shown in FIG. 1 the stamp 1 is completed.

Next, the relationship between the aspect ratio (height H/width W) of the convex parts of the resist pattern Rp before the conductive film 2 is formed and the aspect ratio (height H2/width W2) of the concave parts of the stamp 1 will be described with reference to the drawings.

As described above, by forming the conductive film 2 and the metal film 3 in that order so as to cover the resist pattern Rp, a difference is produced between the membrane stress of the resist layer R that composes the resist pattern Rp and the membrane stress of the conductive film 2 and the metal film 3, so that a force acts so as to cause the resist layer R to shrink. In this case, the inventors confirmed that the higher the aspect ratio of the convex parts of the resist pattern Rp in the state before the conductive film 2 is formed, the higher the aspect ratio of the convex parts in the state after the conductive film 2 and the metal film 3 have been formed (that is, the higher the aspect ratio of the concave parts of the convex/concave pattern of the stamp 1).

More specifically, as shown in FIG. 10, when the aspect ratio of the convex parts of the resist pattern Rp (hereinafter also referred to as the “convex part aspect ratio”) is set at 0.42, the aspect ratio of the concave parts of the convex/concave pattern of the stamp 1 (hereinafter also referred to as the “concave part aspect ratio”) is higher by 0.01 at 0.43, but when the convex part aspect ratio is set at 0.73, the concave part aspect ratio increases to 0.76. Also, when the convex part aspect ratio is set at 1.00, 1.30, 1.76, and 2.41, the concave part aspect ratio increases to 1.16, 1.53, 2.36 and 6.50, respectively. In this case, when the convex part aspect ratio is set at below 1.00, the amount of change between the convex part aspect ratio and the concave part aspect ratio is slight. On the other hand, when the convex part aspect ratio is set at 1.00, the amount of change between the convex part aspect ratio and the concave part aspect ratio becomes relatively large, and as the convex part aspect ratio increases beyond 1.00, the amount of change between the convex part aspect ratio and the concave part aspect ratio gradually increases.

Accordingly, when forming the resist pattern Rp, by forming the convex parts with an aspect ratio of 1.00 or above, it is possible to easily manufacture the stamp 1 including concave parts with a high aspect ratio. Also, to form the mask M with a high aspect ratio so as to increase the recording density of the discrete track medium D, it is preferable to set the concave part aspect ratio of the convex/concave pattern of the stamp 1 at 2.0 or above. Accordingly, to manufacture this kind of stamp 1, when forming the resist pattern Rp, it is necessary to form the convex parts of the resist pattern Rp so that the aspect ratio is 1.6 or above. In this case, to raise the recording density of the discrete track medium D manufactured using this stamp 1, the formation pitch of the data recording tracks (the data recording parts) of the discrete track medium D should preferably be set at 200 nm or below. Accordingly, the formation pitch of the concave parts of the stamp 1 (that is, the formation pitch of the convex parts of the resist pattern Rp) should preferably be set at 200 nm or below.

In this way, according to the manufacturing method for the stamp 1 and the stamp manufacturing apparatus 10 according to the embodiment of the present invention, by manufacturing the stamp 1 by forming the metal film 3 by carrying out a plating process after the conductive film 2 has been formed so as to cover the resist pattern Rp formed on the substrate B, when forming the conductive film 2 and when forming the metal film 3, forces that cause the resist layer R composing the resist pattern Rp to shrink act so that the aspect ratio of the convex parts of the resist pattern Rp (that is, the aspect ratio of the concave parts of the stamp 1) can be increased. Accordingly, it is possible to easily manufacture a stamp 1 with concave parts with a high aspect ratio without forming a resist pattern with convex parts with a high aspect ratio. In this case, by forming the convex parts of the resist pattern Rp with an aspect ratio of 1 or higher, it is possible to reliably manufacture a stamp 1 with concave parts with a sufficiently high aspect ratio. As a result, it is possible to reliably manufacture a stamp 1 that can manufacture a discrete track medium D capable of sufficiently high density recording. Also, by forming the resist pattern Rp by irradiating the resist layer R with the electron beam EB to form the latent images Ri and then developing the resist layer R, it is possible to easily form the convex/concave pattern (the resist pattern Rp) for manufacturing the stamp 1 without using special equipment.

It should be noted that the present invention is not limited to the embodiment described above, and can be modified as appropriate. For example, although an example where a plate-like silicon substrate is used as the support substrate is described in the above embodiment, the present invention is not limited to this, and the stamp 1 can be manufactured using various kinds of support substrates such as a glass substrate or a ceramic substrate. In this case, when using a manufacturing method that uses a support substrate formed of an insulating material and forms the latent images Ri in the resist layer R by irradiating the electron beam EB, to avoid charging up during irradiation with the electron beam EB, the surface of the support substrate should preferably be made conductive. Also, although an example where the resist layer R is formed using a positive-type electron beam resist is described in the above embodiment of the present invention, it is possible to form the resist layer R using various types of resist, such as a negative-type electron beam resist.

Also, although an example where the resist pattern Rp is formed by forming the latent images Ri by irradiating the electron beam EB to the resist layer R and then developing the resist layer R is described in the above embodiment of the present invention, the method of forming the convex/concave pattern in the present invention is not limited to this and the resist pattern Rp may be formed by an imprinting method that forms (transfers) a convex/concave pattern on the substrate B by using an imprint device to press a stamp, in which a convex/concave pattern with a complementary form to the convex/concave pattern formed on the substrate B has been formed, into the resist layer R. By forming the resist pattern Rp using this imprinting method, the resist pattern Rp can be formed without soaking in developer liquid and rinsing liquid, so that even when forming convex parts with a high aspect ratio, it is possible to reliably avoid the collapsing of the convex parts (so-called “pattern collapse”). Accordingly, it is possible to manufacture the stamp 1 with concaves with a high aspect ratio more reliably. In this case, when the convex/concave pattern for manufacturing the stamp is formed by the imprinting method, instead of the above method that forms the resist layer R on the substrate B, in place of the resist it is also possible to form a resin layer of various kinds of resin and to form the convex/concave pattern in this resin layer. In addition, although an example where the conductive film 2 is formed by vapor-depositing nickel so as to cover the resist pattern Rp is described in the above embodiment, the manufacturing method for a magnetic recording medium stamp according to the present invention is not limited to this and it is also possible to form the conductive film 2 by an electroless plating process or sputtering.

1. A manufacturing method for a magnetic recording medium stamp that manufactures a magnetic recording medium stamp for manufacturing a discrete track-type magnetic recording medium, the method comprising:
a step of forming a convex/concave pattern in a resin layer formed on a support substrate;
a step of forming a conductive film so as to cover the convex/concave pattern and then forming a metal film on the conductive film by carrying out a plating process; and
a step of separating a multilayer structure composed of the conductive film and the metal film from the support substrate.

2. A manufacturing method for a magnetic recording medium stamp according to claim 1,
wherein out of convex parts of the convex/concave pattern, convex parts for forming concave parts in parts of the stamp corresponding to a data recording region of the magnetic recording medium are formed with an aspect ratio of 1 or above.

3. A manufacturing method for a magnetic recording medium stamp according to claim 1,
wherein the convex/concave pattern is formed by irradiating an exposure beam to a resist layer as the resin layer to form a latent image and then developing the resist layer.

4. A manufacturing method for a magnetic recording medium stamp according to claim 1,
wherein the convex/concave pattern is formed by an imprinting method.

5. A manufacturing apparatus for a magnetic recording medium stamp that manufactures a magnetic recording medium stamp for manufacturing a discrete track-type magnetic recording medium, the manufacturing apparatus comprising:
a resin layer forming device that forms a resin layer on a support substrate;
a convex/concave pattern forming device that forms a convex/concave pattern in the resin layer;
a conductive film forming device that forms a conductive film so as to cover the convex/concave pattern; and
a metal film forming device that forms a metal film on the conductive film by carrying out a plating process.

6. A manufacturing apparatus for a magnetic recording medium stamp according to claim 5,
wherein the convex/concave pattern forming device includes:
an exposing device that irradiates an exposure beam to a resist layer as the resin layer to form a latent image; and
a developing device that forms the convex/concave pattern by developing the resist layer in which the latent image has been formed.

7. A manufacturing apparatus for a magnetic recording medium stamp according to claim 5,
wherein the convex/concave pattern forming device includes an imprinting device that forms the convex/concave pattern by carrying out an imprinting method.
